(19) United States
(12) Patent Application Publication
(10) Pub. No.: US 2006/0243968 A1
(43) Pub. Date: Nov. 2, 2006

(54) Organic electroluminescent device for preventing long distance short

(76) Inventors: Chin Chung Chang Chien, Chu-Nan (TW); Hui-Chang Yu, Chu-Nan (TW); Wei-Wen Yang, Chu-Nan (TW); Chia-Mei Liu, Chu-Nan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/409,972

(22) Filed: Apr. 25, 2006

(30) Foreign Application Priority Data
Apr. 29, 2005 (TW) 094114055

(51) Int. Cl. H01L 29/08

(52) U.S. Cl. 257/40

(57) ABSTRACT

An organic electroluminescent device for preventing long distance short comprises an isolated separating layer unit provided on an organic light emitting layer and the two sides of an second electrode, and an isolating trench further provided between a first isolated separating layer and a second isolated separating layer of the isolated separating layer unit. Accordingly, the isolating trench is provided for preventing the irregular electrical contact from the first electrical conducting layer of the top of the first isolated separating layer and the second electrical conducting layer of the top of the second isolated separating layer, that is, the irregularly lighting by the pixels can be prevented from the long distance short for the organic electroluminescent device.

### FIELD OF THE INVENTION

The present invention relates to an organic electroluminescent device, and more particularly to an organic electroluminescent device for preventing long distance short.

### BACKGROUND OF THE INVENTION

In view of many displayers and light emitting devices, such as the organic electroluminescent device provides many advantages as self-illumination, high brightness, wide viewing angle, low power consumption, high response speed, and thin panel, which is surely paid attention by every manufacture and research institution.

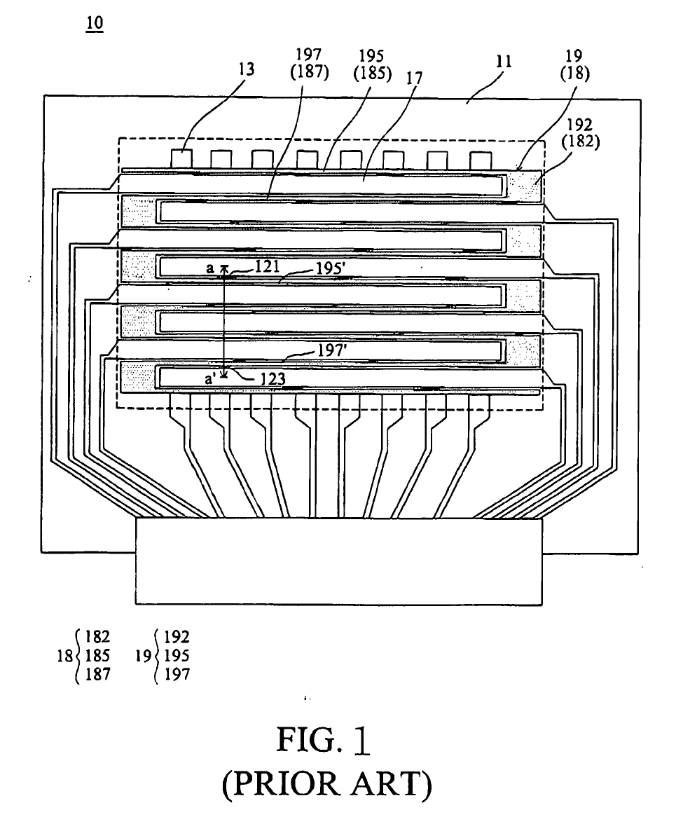

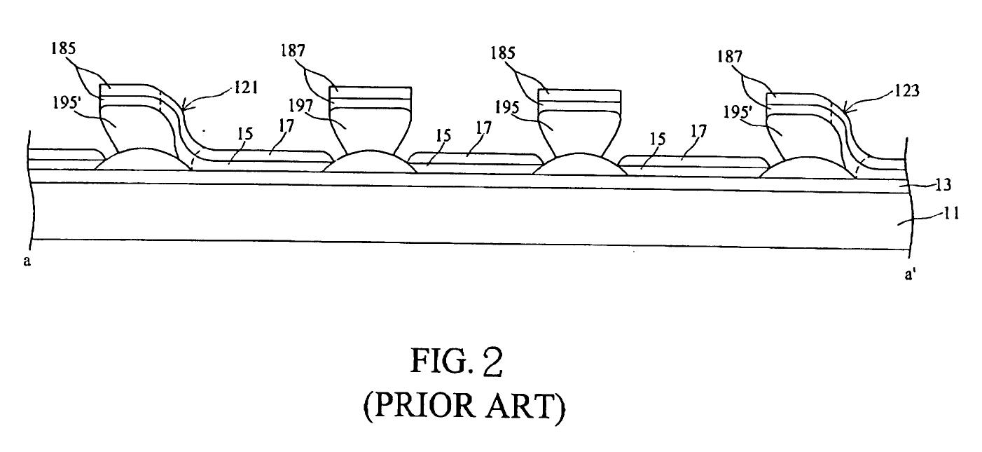

Referring to FIG. 1 and FIG. 2, FIG. 1 shows the structure of a prior art organic electroluminescent device. FIG. 2 shows cross-sectional to a-a′ of FIG. 1. The organic electroluminescent device 10 comprises at least one first electrode 13 provided on the surface of a substrate 11, and an isolated separating layer 19 provided on the surface of the partial first electrodes 13 and the substrate 11, wherein the isolated separating layer 19 comprises a plurality of isolated separating units, each of the isolated separating units comprises a first isolated separating layer 195 and a second isolated separating layer 197. The first isolated separating layer 195 is connected to the second isolated separating layer 197 by a connecting section 192. Accordingly, the isolated separating layer 19 is provided for advantaging the further process of the organic electroluminescent device 10 manufacturing. For example, an organic light emitting layer 15 and an second electrode 17 are formed between the first isolated separating layer 195 and the second isolated separating layer 197, wherein the first isolated separating layer 195 and the second isolated separating layer 197 should be precisely aligned. However, as the organic light emitting layer 15 and an second electrode 17 are formed, an electrical conducting layer 18 is grown on the surface of the first isolated separating layer 195, the connecting section 192, and the second isolated separating layer 197, wherein the electrical conducting layer 18 is made by the same material with the organic light emitting layer 15 and the second electrode 17, such as the first conducting layer 185 provided on the top of the first isolated separating layer 195, the second conducting layer 187 provided on the top of the second isolated separating layer 197, and the conducting layer of connecting section 182 provided on the top of the connection section 192. Basically, if the isolated separating layer 19 is as general status, the first electrical conducting layer 185, the second electrical conducting layer 187, and the conducting layer of connecting section 182 should not be without working current, but if the isolated separating layer 19 is with at least two structure-weak sections, such as shown on Figs, the first isolated separating layer 195′ and the second isolated separating layer 197′, then a first conducting section 121 will be formed on the partial side of the first isolated separating layer 195′, or a second conducting section 123 will be formed on the partial side of the second isolated separating layer 197′. The working current is transmitted from the second electrode 17 to the electrical conducting layer 18 of the top of the isolated separating layer 19 through the first conducting section 121 or the second conducting section 123, and further passing through the first electrical conducting layer 185, the second electrical conducting layer 187, and the conducting layer of connecting section 182 to the second electrode 17 being adjacent the first isolated separating layer 195′ or the second isolated separating layer 197′. Such that, the organic electroluminescent device 10 may have problems of long distance short and pixels lighting irregularly so as to affect the yield of the organic electroluminescent device manufacturing.

### SUMMARY OF THE INVENTION

Accordingly, how to design a novel organic electroluminescent device for preventing long distance short with respect to the previous mentioned shortcomings of the prior art, that is, preventing long distance short and pixels lighting irregularly from the partial weak structure of the isolated separating layer is the key point of the present invention. Therefore,

It is a primary object of the present invention to provide an organic electroluminescent device for preventing long distance short, comprising an isolating trench provided on the connecting section when the isolated separating layer is provided, which for preventing the electrical contact of the first isolated separating layer and the second isolated separating layer so that can be used for preventing pixels lighting irregularly from the long distance short for the organic electroluminescent device.

It is a secondary object of the present invention to provide an organic electroluminescent device for preventing long distance short, which can increase the yield of the product manufacturing, according to the isolating trench easily provided.

To achieve the previous mentioned objects, the present invention provides an organic electroluminescent device for preventing long distance short comprises a substrate; at least one first electrode provided on the substrate; a plurality of isolated separating layer units provided on the first electrode and the substrate, and being as intersection with the first electrode, each of the isolated separating layer units comprising a first isolated separating layer and a second isolated separating layer, wherein an isolating trench provided on a side of the first isolated separating layer and a corresponding side of the second isolated separating layer to prevent electrical contacting from the first isolated separating layer and the second isolated separating layer. At least one organic light emitting layer is provided between the first isolated separating layer and the second isolated separating layer, contacting with the first electrode; and at least one second electrode provided on the organic light emitting layer.

### BRIEF DESCRIPTION OF THE DRAWRNGS

It will be understood that the figures are not to scale since the individual layers are too thin and the thickness differences of various layers too great to permit depiction to scale.

FIG. 1 is a vertical view of a prior art organic electroluminescent device;

FIG. 2 is a cross-sectional view of the prior art organic electroluminescent device;

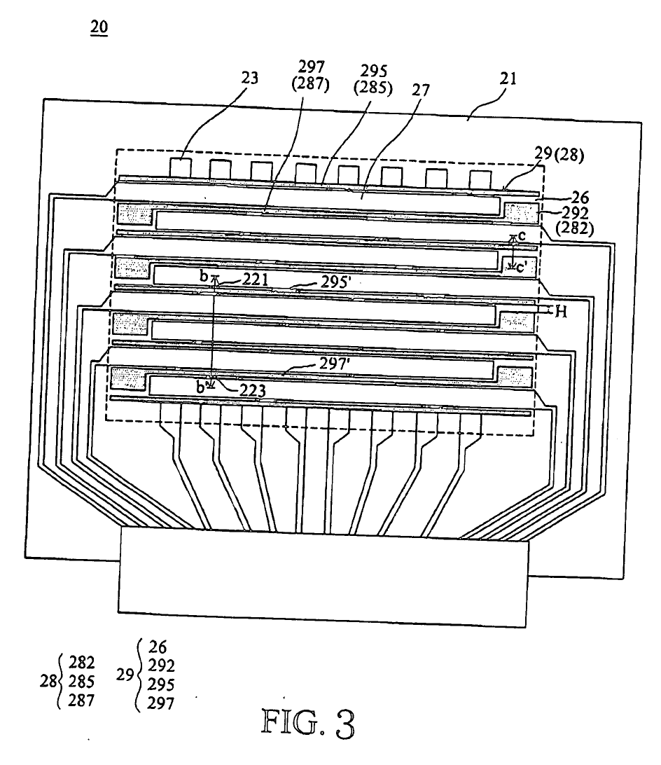

FIG. 3 is a vertical view of a preferred embodiment of the present invention organic electroluminescent device;

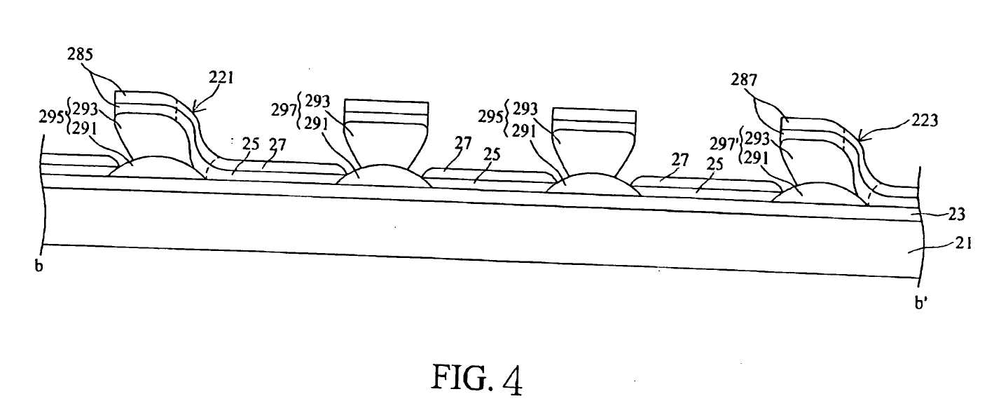

FIG. 4 is a cross-sectional view of the preferred embodiment of the present invention;

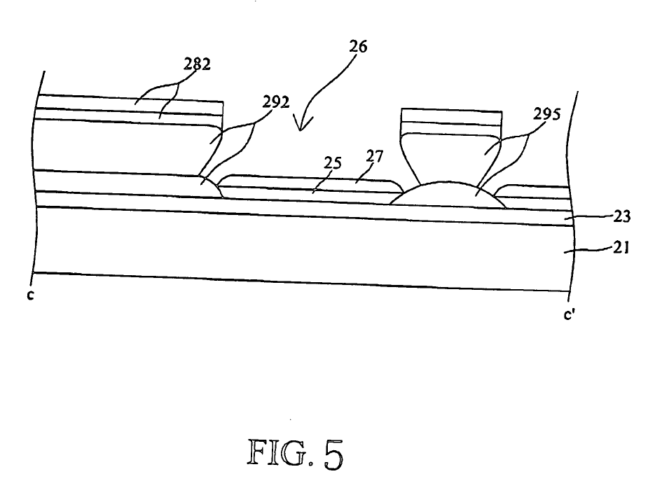

FIG. 5 is a cross-sectional view of the preferred embodiment of the present invention; and

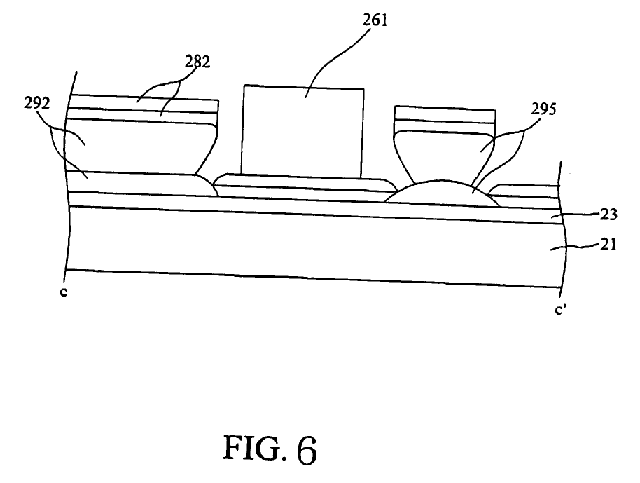

FIG. 6 is a cross-sectional view of another preferred embodiment of the present invention.

### DETAILED DESCRIPTION OF THE INVENTION

The structural features and the effects to be achieved may further be understood and appreciated by reference to the presently preferred embodiments together with the detailed description.

Referring to FIG. 3, FIG. 4 and FIG. 5, FIG. 3 shows a vertical view of a preferred embodiment of the present invention organic electroluminescent device. FIG. 4 shows a cross-sectional view to b-b′ of FIG. 3. FIG. 5 shows a cross-sectional view to c-c′ of FIG. 3. The organic electroluminescent device 20 comprises at least one first electrode 23 provided on the partial area of the surface of a substrate 21, at least one isolated separating layer 29 provided on the partial surface of the first electrode 23 and the substrate 21, and the isolated separating layer 29 being as intersection with the first electrode 23. The isolated separating layer 29 consists of a plurality of isolated separating layer units. Each isolated separating layer unit comprises a first isolated separating layer 295, a second isolated separating layer 297, and an isolating trench 26. The isolating trench 26 is provided on the side of the first isolated separating layer 295 and a corresponding side of the second isolated separating layer 297 for separating the first isolated separating layer 295 and the second isolated separating layer 297. And, at least one organic light emitting layer 25 is provided on the first isolated separating layer 295 and the second isolated separating layer 297. Further, an second electrode 27 is provided on the surface of the organic light emitting layer 25.

The area between the first isolated separating layer 295 and the second isolated separating layer 297 of the isolated separating layer unit, further provides a connecting section 292. The connecting section 292 is provided on the side of the first isolated separating layer 295, and connected with the side of the second isolated separating layer 297 corresponding with the side of the first isolated separating layer 295.

And, the isolated separating layer 29 consists of an insulator 291 and a separator 293, which for advantaging the organic light emitting layer 25 and the second electrode provided, and defining the pixels from the organic electroluminescent device 20. Furthermore, a first electrical conducting layer 285 is provided on the surface of the first isolated separating layer 295, the connecting section 292, and the second isolated separating layer 297, made by the same material with the organic light emitting layer 25 and the second electrode 27, when the organic light emitting layer 25 and the second electrode 27 are provided, such as the first electrical conducting layer 285 of the top of the first isolated separating layer 295, the second electrical conducting layer 287 of the top of the second isolated separating layer 297, and the connecting-section conducting layer 282 of the top of the connecting section 292. The electrical conducting layer 28 (such as the first electrical conducting layer 285, the second electrical conducting layer 287, and the connecting-section conducting layer 282) is selected to be stacked by the second electrode 27 or the organic light emitting layer 25 and the second electrode 27.

When the isolated separating layer 29 is with partial weak structure, such as the first isolated separating layer 295′ or the second isolated separating layer 297′ shown on FIG. 4, then a first conducting section 221 is formed on the partial area of the first isolated separating layer 295′, or a second conducting section 223 is formed on the partial area of the second isolated separating layer 297′. And, the working current is transmitted from the second electrode 27 to the electrical conducting layer 28 of the top of the isolated separating layer 29 through the first conducting section 221 or the second conducting section 223. Further, the isolating trench 26 is provided for preventing the working current to be transmitted to another adjacent first isolated separating layer 295′ or second isolated separating layer 297′ by passing through the first electrical conducting layer 285, the second electrical conducting layer 287, and the connecting-section conducting layer 282, which for preventing the long distance short for the organic electroluminescent device 20 and the lighting irregularly by the pixels. Thus, the purpose of increasing the yield of the organic electroluminescent device 20 can be achieved.

Furthermore, the reserved place for the isolating trench 26 within the first isolated separating layer 295, the connecting section 292, and the second isolated separating layer 297, consists of the separator 291 and the insulator 293, as shown on FIG. 5. Therefore, when the organic light emitting layer 25 and the second electrode 27 are provided, which have to be separated by the first isolated separating layer 295 and the second isolated separating layer 297, the isolating trench 26 can be used for isolating the electrical conducting layer 28 of the top of the first isolated separating layer 295, the connecting section 292, and the second isolated separating layer 297.

The width H of the isolating trench 26 can be adjusted by demanding from different products. For example, the width H of the isolating trench 26 can be the same with the connecting section 192 of the prior art structure. In other words, the connecting section 192 can be replaced by the isolating trench 26.

Referring to FIG. 6, is a cross-sectional view of another c-c′ of FIG. 4. The organic electroluminescent device 20 further comprises an isolating wall 261 provided on the isolating trench 26 within each isolated separating layer unit 29. The isolating wall 261 is made by a high impedance material. Thus, the dielectric constant between each adjacent isolated separating layer 29 can be increased. And, the conduction probability from the isolated separating layer 29 each other can be reduced.

The foregoing description is merely one embodiment of present invention and not considered as restrictive. All equivalent variations and modifications in process, method, feature, and spirit in accordance with the appended claims may be made without in any way from the scope of the invention.

I claim:

1. An organic electroluminescent device for preventing long distance short, comprising:
a substrate;
at least one first electrode provided on said substrate;
a plurality of isolated separating layer units provided on said first electrode, and being as intersection with said first electrode, each of said isolated separating layer units comprising a first isolated separating layer and a second isolated separating layer, wherein a isolating trench provided on a side of said first isolated separating layer and a corresponding side of said second isolated separating layer to prevent electrical contacting from said first isolated separating layer and said second isolated separating layer;
at least one organic light emitting layer provided between said first isolated separating layer and said second isolated separating layer, and contacting with said first electrode; and
at least one second electrode provided on said organic light emitting layer.

2. The organic electroluminescent device of claim 1, wherein said isolated separating layer units comprises an insulator and a separator.

3. The organic electroluminescent device of claim 1, wherein said isolating trench comprises an isolating wall.

4. The organic electroluminescent device of claim 1, wherein said isolated separating layer unit further comprises a connecting section connected with one of the side of said first isolated separating layer and said second isolated separating layer.

5. The organic electroluminescent device of claim 1, wherein a electrical conducting layer is formed on said first isolated separating layer and said second isolated separating layer, said electrical conducting layer comprises said second electrode.
